(19) United States
(12) Patent Application Publication
(10) Pub. No.: US 2007/0051949 A1
(43) Pub. Date: Mar. 8, 2007

(54) Method and arrangment for testing a stacked die semiconductor device

(76) Inventors: Peter Schneider, Williston, VT (US); Dawn C. Cutler, Williston, VT (US)

Correspondence Address: EDELL, SHAPIRO & FINNAN, LLC, 1901 RESEARCH BLVD., SUITE 400, ROCKVILLE, MD, 20850, US

(21) Appl. No.: 11/218,636

(22) Filed: Sep. 6, 2005

(51) Int. Cl. H01L 23/58

(52) U.S. Cl. 257/48

(57) ABSTRACT

A semiconductor device and related testing methods and configurations are provided to enable parallel (simultaneous) testing of multiple chips on a stacked multiple chip semiconductor device. Each chip in the device is configured to selectively output test results to one or more unique contacts on a substrate of the device.

### FIELD OF THE INVENTION

This invention relates to semiconductor devices, and more particularly to a configuration for simultaneously testing a plurality of chips or dies of a stacked die semiconductor device.

### BACKGROUND OF THE INVENTION

Semiconductor devices may be packaged in various ways depending on the application of the device. One packaging technique involves stacking multiple semiconductor integrated circuit “chips” or dies, and routing connection traces from a common substrate to each chip. A stacked die package is common in semiconductor memory device applications, such as dynamic random access memory (DRAM) devices.

A stacked die device presents challenges when testing the device. In current designs, an example of which is shown in FIG. 1, similar function pins on each die are connected to the similar function contacts on the substrate. There is a top die or chip 10, a bottom chip 20 and a substrate 30. A so-called “DQ” or pin, such as DQ0 on each chip is connected to the DQ0 contact on the substrate 30. As a result, during test mode procedures, the individual dies can be tested sequentially, rather than in parallel. Only DC tests of the dies can be performed in parallel. Conducting functional tests sequentially on multiple dies of the device lengthens the time required to fully test the device.

This is a major obstacle. As mentioned above, in a multiple stacked die device the same DQs on each of the dies are bonded to the same DQ trace on the substrate. Therefore, test result data signals from a test procedure conducted on the dies would interfere with each other if read out simultaneously through the contacts on the substrate.

Most semiconductor memory devices utilize a type of data compression test mode that writes the result of a functional test through one or more pins to the test device. In current memory device designs, the DQ(s) is/are fixed and there is only one possible DQ or DQ combination that is allowed to be used for a particular functional test. It is not possible to choose which DQ (or DQ combination) outputs the signal that is sent to the test device.

In order to save a considerable amount of time and test device resources when performing functional tests, it would be desirable to test the individual dies on a stacked semiconductor device in parallel.

### SUMMARY OF THE INVENTION

Briefly, a semiconductor device and related testing methods and configurations are provided to enable parallel (simultaneous) testing of multiple chips on a stacked multiple chip semiconductor device. Each chip has a plurality of pins and a circuit that routes results from a test procedure to select ones of the plurality of pins that are in turn connected to corresponding contacts on the device. Thus, each chip in the device is configured to output test results to one or more unique contacts on a substrate of the device. In this way, functional tests can be simultaneously conducted on each of the chips and the test results are output substantially simultaneously from different contacts on the semiconductor device to the test device.

### BRIEF DESCRIPTION OF THE DRAWINGS

FIG. 1 is a block diagram of the prior art.

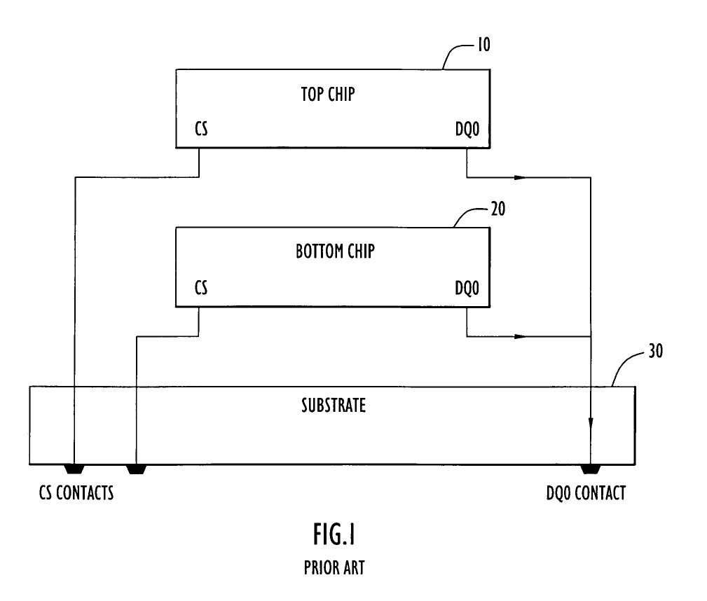

FIG. 2 is a block diagram of an embodiment of the invention.

FIG. 3 is a block diagram of another embodiment of the invention.

FIG. 4 is a block diagram of a stacked die semiconductor device configured as shown in FIGS. 2 or 3, and illustrating configuration and operation of a test procedure according to an embodiment of the invention.

FIG. 5 is a flow chart depicting a test procedure according to an embodiment of the invention.

### DETAILED DESCRIPTION

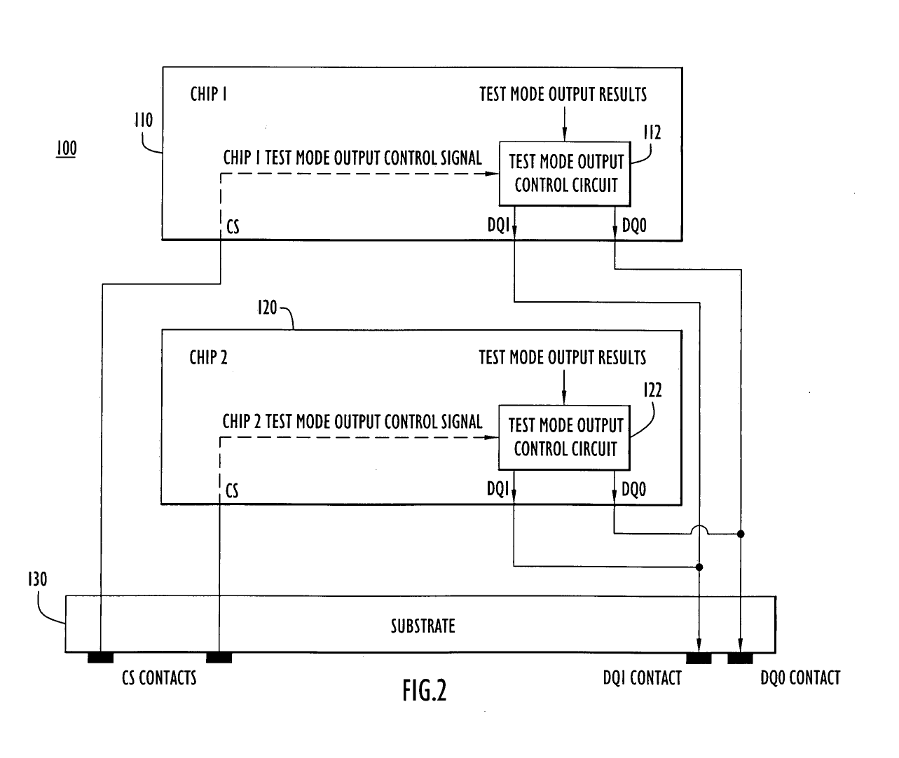

Referring first to FIG. 2, a stacked multiple die (or multiple chip) semiconductor device is shown at reference numeral 100. The terms “die” and “chip” are used interchangeably herein. The device 100 comprises at least two dies stacked on each other. In the example shown in FIG. 2, there are two chips 110 and 120. It should be understood that the techniques described herein may be applied to a device that has more than two chips. The chips 110 and 120 are stacked on each other and on a substrate 130. The device 100 may be, for example, a dynamic random access memory (DRAM) device, where chips 110 and 120 are essentially the same type of memory chip.

For this invention, in a stacked die device such as the one shown in FIG. 2, each chip contains its own test mode output control circuit. Specifically, chip 110 has test mode output control circuit 112 and chip 120 has test mode output control circuit 122.

The output control circuitry of each chip is connected to the DQs, or pins, of that chip. Each chip communicates with the outside world through these DQs, which are connected by conductive traces to corresponding contacts on the substrate 130. The contacts on the substrate 130 receive input signals and deliver output signals. For example, on chip 110, DQ0 and DQ1 are connected to, respectively, DQ0 and DQ1 contacts on the substrate 130. Similarly, on chip 120, DQ0 and DQ1 are connected to, respectively, DQ0 and DQ1 contacts on the substrate 130. Because only one DQ (or combination of a plurality of DQs) on a chip is used to send test result data to the test device, there are DQ pins on the die and on the substrate that are available for rerouting the compressed test results data

To test the chips in parallel, the test mode output control circuits 112 and 122 must ensure that each chips' data is output to a unique DQ. In order to execute a test procedure on the chips 110 and 120 simultaneously, one of the chips is configured to output its test result on DQ0 and the other is configured to output its test result on DQ1. In this way, a test device can supply test signals to effect a similar functional test to both chips simultaneously, and receive the results simultaneously on different (unique) contacts on the substrate 130.

A test sequence would proceed as follows. Test mode output control circuit 112 on chip 110 is responsive to a first test mode output control signal and test mode output control circuit 122 is responsive to a second test mode output control signal. The test mode control signals are supplied to the chips 110 and 120 via corresponding contacts on the substrate 130. For example, the chip select (CS) contacts on the substrate 130 receive from a test device (not shown in FIG. 2) corresponding test mode output control signals. The respective test mode output control signals are then supplied to the corresponding test mode output control circuit.

In each chip, the results of a test procedure executed on that chip are coupled to its test mode output control circuit. Test mode output control circuit 112 is responsive to the first test mode output control signal to selectively route the test result to its DQ0 or DQ1. Similarly, test mode output control circuit 122 is responsive to the second test mode output control signal to selectively route the test result to its DQ0 or DQ1. This test mode allows the test device programmer/controller to determine on which DQ(s) the result of the functional test is/are output.

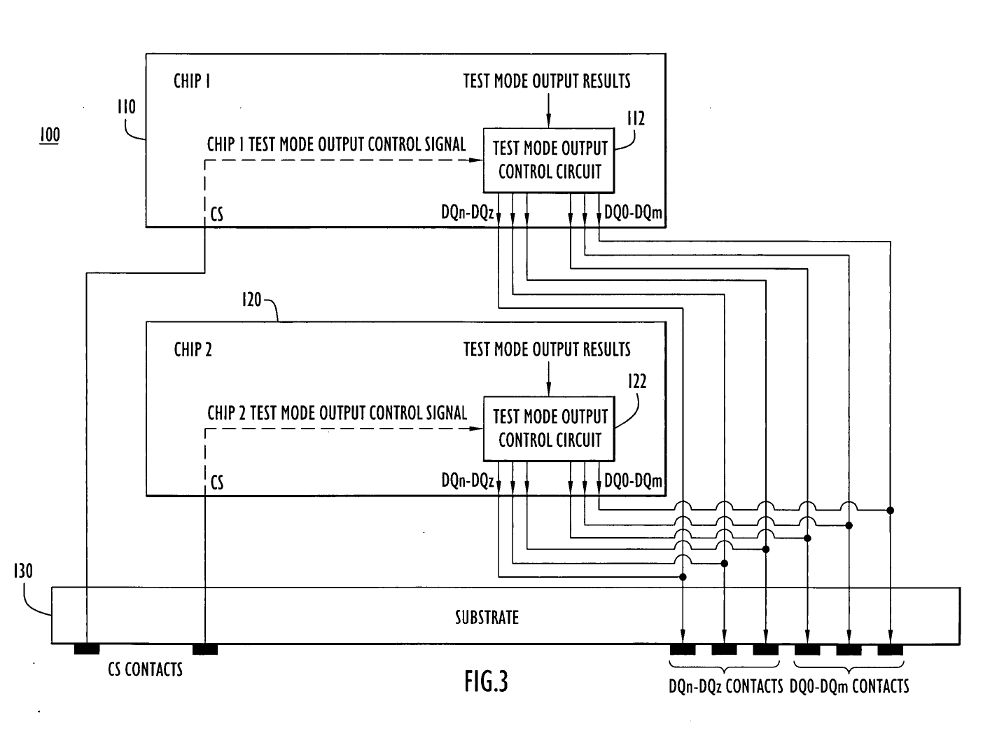

FIG. 3 illustrates a configuration similar to FIG. 2, except that the test results are output from a combination of a plurality of DQs on each chip to corresponding DQ contacts on the substrate 130. Specifically, test mode output control circuit 112 in chip 110 selectively routes test results data either to a first plurality of DQs denoted DQ0-DQm or to a second plurality of DQs denoted DQn-DQz. Similarly, test mode output control circuit 122 in chip 120 selectively routes test results data either to a first plurality of DQs denoted DQ0-DQm or to a second plurality of DQs denoted DQn-DQz. DQ0-DQm contacts and DQn-DQz contacts on the substrate 130 are connected by conductive traces to the corresponding denote DQs on both the first chip 110 and the second chip 120. Test mode output control signals are supplied to the chips 110 and 120 via CS contacts on the substrate 130. Thus, the configuration of FIG. 3 is an extension of the arrangement shown in FIG. 2 to support the routing of test results data that consists of multiple bits that consequently need to be routed by multiple DQs (rather than a single DQ as shown in FIG. 2) on each chip to corresponding DQ contacts on the substrate.

The test mode output control circuits 112 and 122 may be implemented in the spine of the corresponding chips 110 and 120. Examples of a circuit suitable for the test mode output control circuits 112 and 122 include a demultiplexer circuit or a decoder circuit. If the test result consists of one-bit data, then the demultiplexer circuit may be a 1×2 demultiplexer circuit having one input, two outputs and a single bit select control. In general, if the test results consist of n-bit data, then the demultiplexer circuit would be an n×2n demultiplexer circuit. The test mode output control signal is coupled to the select control of the demultiplexer circuit.

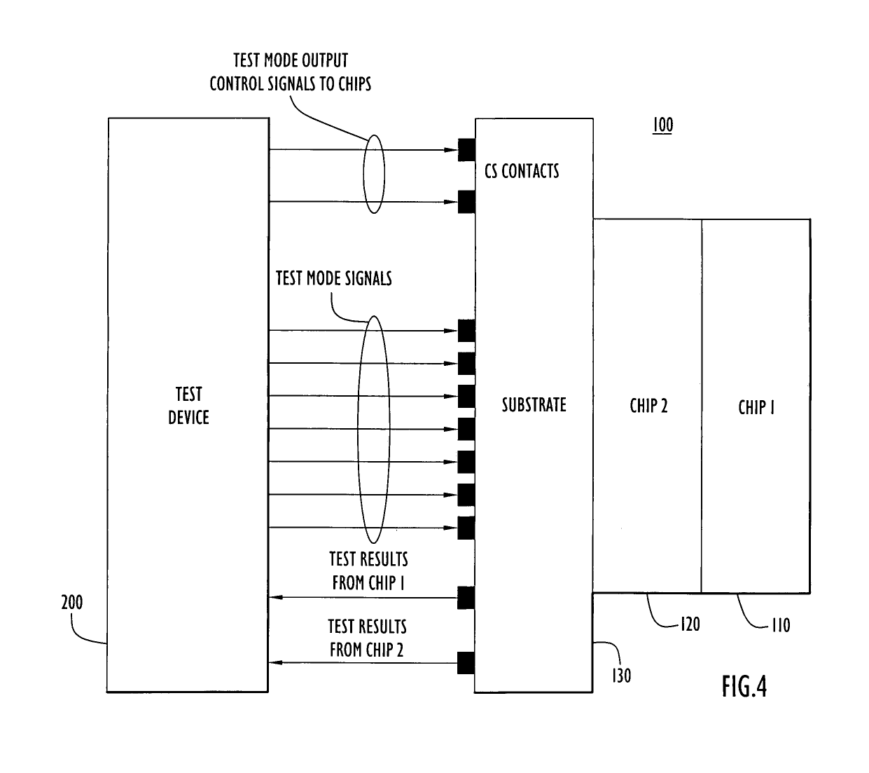

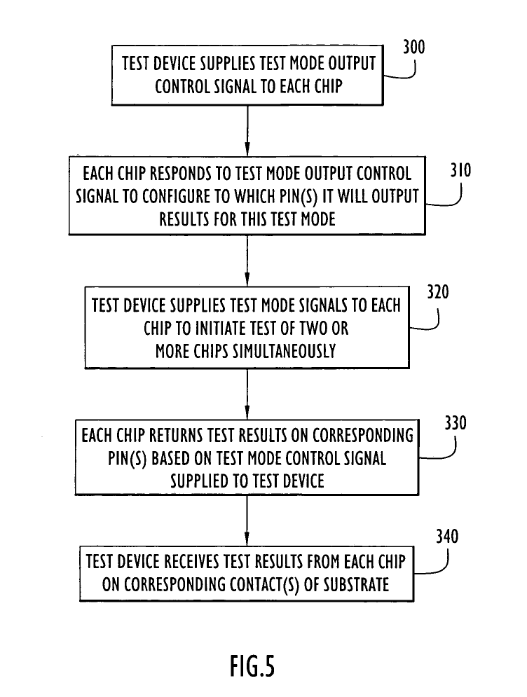

Turning to FIGS. 4 and 5, operation of the test mode configuration according to the present invention will be described. A test device 200 is coupled to the contacts on the substrate of a stacked multiple die device 100. The test device 200 has a plurality of contacts that connect to corresponding contacts on the device 100 to be tested. Once the test device 200 is in position, in step 300 the test device supplies test mode output control signals to each chip to program each chip where to route its test result(s). For example, as shown in FIGS. 2 and 3, the test device generates test mode output control signals that are supplied to corresponding CS contacts on the device 100, which are in turn connected by conductive traces to the CS pin on the chips 110 and 120. In step 310, the test mode output control circuit in each chip responds to its corresponding test mode output control signal to select on which pin(s) (DQ or DQs) it will route results for the test procedure.

Next, in step 320, the test device 200 supplies test mode signals to each chip via appropriate contacts on the substrate to initiate a test mode procedure simultaneously on two or more chips. In step 330, each chip returns its test results on corresponding pins based on the output configuration information carried by its test mode output control signal supplied in step 310. In step 330, the test device 200 substantially simultaneously receives the test results from each chip from the corresponding contact(s) on the substrate 130 of the device 100.

The test mode configuration described herein allows the test device to determine on which DQ the result of the functional test under data compression is routed, thereby enabling the data from each chip to be simultaneously routed to different contact pads on the substrate. Thus, functional tests may be made on stacked chips in parallel. These techniques may be applied to any type of semiconductor device that stacks multiple integrated circuit dies on top of each other. A semiconductor DRAM device is only one example of such a device. In the context of a semiconductor DRAM devices, this invention facilitates testing of dual die DRAM devices with a time savings of approximately 47% of the test time of the corresponding functional DRAM tests if conducted sequentially.

With these techniques, conventional test device equipment can be used to test stacked die devices much faster than prior art sequential functional test procedures. Significant test coverage associated with the test procedures is retained as well, yet with enhanced flexibility as a result of the selective output of test result data. Moreover, the techniques described herein can be used with any data compression scheme associated with a test mode.

Although the present invention and its advantages have been described in detail, it should be understood that various changes, substitutions and alterations can be made herein without departing from the spirit and scope of the invention as defined by the appended claims.

What is claimed is:

1. A method for testing a semiconductor device, comprising: substantially simultaneously executing a test procedure on two or more semiconductor dies in the device, wherein each die outputs test results from the test procedure to a corresponding unique contact on the semiconductor device.

2. The method of claim 1, and further comprising programming each die to selectively output a test result to a pin that is connected to the corresponding unique contact on the device.

3. The method of claim 1, wherein programming comprises programming each die to selectively output test results to a plurality of pins that are connected to a corresponding unique plurality of contacts on the device.

4. The method of claim 1, wherein programming comprises transmitting a signal from a test device connected to the device that configures each die to output its test results to said pin that is connected to the corresponding unique contact on the device.

5. A method for configuring a semiconductor device for simultaneously testing multiple stacked dies in the semiconductor device, comprising: programming each die so as to selectively output a test result to a corresponding unique contact on the semiconductor device.

6. The method of claim 5, and further comprising programming each die to output a test result to a pin that is connected to the corresponding unique contact on the device.

7. The method of claim 5, wherein programming comprises programming each die to output test results to a plurality of pins that are connected to a corresponding unique plurality of contacts on the device.

8. The method of claim 5, wherein programming comprises transmitting a signal from a test device connected to the device that configures each die to output its test results to said pin that is connected to the corresponding unique contact on the device.

9. A method for testing a semiconductor device comprising a plurality of stacked dies, comprising:
a. connecting a test device to the semiconductor device;
b. transmitting a signal from the test device to each die of the device that configures the die to output test results from a pin that is connected to a corresponding unique contact on the device;
c. transmitting a test signal from the test device to each of the dies in order to substantially simultaneously execute a test procedure on the plurality of dies; and
d. substantially simultaneously receiving at the test device from the corresponding unique contacts the test results output by each of the plurality of dies.

10. The method of claim 9, and wherein (b) transmitting comprises transmitting a signal from the test device to a chip select pin associated with each die on the device.

11. A semiconductor device comprising at least first and second dies stacked on one another, wherein each of the first and second dies has a plurality of pins and a circuit that selects to which of its plurality of pins a result from a test procedure is output.

12. The device of claim 11, and further comprising a plurality of contacts that are connected to corresponding pins on the first and second dies.

13. The device of claim 12, wherein said circuit on the first die and said circuit on the second die selectively route test results from the first and second dies, respectively, to different contacts on the semiconductor device.

14. The device of claim 12, wherein said circuit on the first die and said circuit on the second die selectively route test results from the first and second dies, respectively, to different pluralities of contacts on the semiconductor device.

15. The device of claim 12, wherein said circuit on the first and second dies is a demultiplexer circuit.

16. A stacked multiple chip semiconductor device comprising:
a. a substrate having a plurality of contacts to which signals to the device are input and from which signals are output; and
b. at least first and second integrated circuit chips stacked on one another and supported on said substrate, wherein each of the first and second chips has a plurality of pins that are connected to corresponding contacts on the substrate, and means for selectively routing a result from a test procedure to at least one of the plurality of pins of the chip that is in turn connected to a corresponding contact on the substrate for output to a test device.

17. The device of claim 16, wherein the means for selecting on each chip selectively routes test results from the first and second chips, respectively, to different pluralities of contacts of the substrate.

18. The device of claim 16, wherein the means for selecting comprises a demultiplexer circuit.

19. A stacked multiple chip semiconductor device comprising:
a. a substrate having a plurality of contacts; and
b. a plurality of integrated circuit chips stacked on one another and supported on said substrate, wherein each of the chips has a plurality of pins that are connected to corresponding contacts on the substrate, and a circuit that selects at least one of the plurality of pins to which a result from a test procedure is routed so that the test results from test procedures executed on two or more of the plurality of chips are provided at substantially the same time on different pluralities of contacts of the substrate.

20. The device of claim 19, wherein said circuit on each of the plurality of chips is responsive to a corresponding control signal supplied to it via a contact on the substrate.

21. An semiconductor integrated circuit device, comprising:
a. a plurality of pins; and
b. a circuit that selectively routes results from a test procedure to one or more of the plurality pins.
